(19) United States
(12) Patent Application Publication
(10) Pub. No.: US 2025/0203828 A1
(43) Pub. Date: Jun. 19, 2025

(54) REDUCTION OF RADIATED EMISSIONS USING SPARSE MESH ADDITIVE MATERIAL

(71) Applicant: Cisco Technology, Inc., San Jose, CA (US)

(72) Inventors: Shadi EBRAHIMI ASL, Raleigh, NC (US); Phong H. HO, Cary, NC (US); Stephen A. SCEARCE, Apex, NC (US)

(21) Appl. No.: 18/930,089

(22) Filed: Oct. 29, 2024

Related U.S. Application Data
(60) Provisional application No. 63/609,803, filed on Dec. 13, 2023.

(51) Int. Cl. H05K 9/00

(52) U.S. Cl. CPC H05K 9/0041; H05K 9/0049

(57) ABSTRACT

Embodiments presented in this disclosure relate to the reduction of radiated emissions in electronic devices through the use of a mesh with a sparse cell structure. One embodiment includes a conductive panel comprising a plurality of ventilation holes, each ventilation hole having an inner perimeter. A mesh is attached to the conductive panel, the mesh comprising a plurality of cells, where each respective cell encloses the inner perimeter of a respective ventilation hole to form a conductive barrier around each respective ventilation hole.

### CROSS-REFERENCE TO RELATED APPLICATIONS

This application claims benefit of co-pending U.S. provisional patent application Ser. No. 63/609,803 filed Dec. 13, 2023. The aforementioned related patent application is herein incorporated by reference in its entirety.

### TECHNICAL FIELD

Embodiments presented in this disclosure generally relate to radiation shielding. More specifically, embodiments disclosed herein relate to reducing radiated emissions in electronic devices using a mesh with a sparse cell structure.

### BACKGROUND

Holes in panels or sides of electronic devices are used for air ventilation purposes. Normally, these holes are punched or machined into a metal panel with a thickness ranging from 1 to 1.4 mm. These holes are often hexagonal. The average diameter of these holes often ranges between 2.0 and 5 mm. The dimensions of these holes depend on the thermal requirements of the electronic devices. While these holes are primarily provided for airflow to aid in thermal dissipation, electromagnetic waves and radiation from inside the devices may also escape through these holes. As network devices, such as routers and switches, are being developed to operate at higher frequencies (e.g., 25 GHz and above), the wavelength of the radiated signal inside the enclosure reduces significantly (e.g., approximately 1.2 cm for 25 GHz). When the wavelength of these signals becomes on the order of the size of the ventilation holes, energy starts leaking out of the device enclosure through these holes, potentially causing interference to neighboring devices.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 shows an example router with panels for EMI shielding, according to some embodiments of the present disclosure.

FIG. 2 shows an example panel with ventilation holes, according to some embodiments of the present disclosure.

FIG. 3 shows an example panel with added sparse mesh for enhanced EMI shielding, according to some embodiments of the present disclosure.

FIG. 4 shows a close-up view of a panel with added sparse mesh, according to some embodiments of the present disclosure.

FIG. 5 shows a close-up view of a panel with added structural supports between mesh cells, according to some embodiments of the present disclosure.

FIG. 6 shows EMI performance of a device across signal frequencies with different panel configurations, according to some embodiments of the present disclosure.

FIG. 7 shows an example method for manufacturing a panel with sparse mesh for enhanced EMI shielding, according to some embodiments of the present disclosure.

FIG. 8 is a flow diagram depicting an example method for forming an enclosure with reduced radiated emission, according to some embodiments of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure provides an enclosure for an electronic device. The enclosure comprises a conductive panel comprising a plurality of ventilation holes, each ventilation hole having an inner perimeter, and a mesh attached to the conductive panel, the mesh comprising a plurality of cells, where each respective cell encloses the inner perimeter of a respective ventilation hole to form a conductive barrier around each respective ventilation hole.

One embodiment presented in this disclosure provides a method for forming an enclosure for an electronic device to shield electromagnetic interference, comprising preparing a conductive panel comprising a plurality of ventilation holes, each ventilation hole having an inner perimeter, fabricating a mesh comprising a plurality of cells, and attaching the mesh to the conductive panel, where each respective cell encloses the inner perimeter of a respective ventilation hole to form a conductive barrier around each respective ventilation hole.

One embodiment presented in this disclosure provides an apparatus for shielding electromagnetic interference in an electronic device comprising a conductive panel comprising a plurality of ventilation holes, each ventilation hole having an inner perimeter, and a mesh attached to the conductive panel, the mesh comprising a plurality of cells, where each respective cell encloses the inner perimeter of a respective ventilation hole to form a conductive barrier around each respective ventilation hole.

### EXAMPLE EMBODIMENTS

Network devices often use metal panels as enclosures to shield radiation from escaping outside. This practice is implemented to satisfy regulatory requirements for electromagnetic interference (EMI) control. Additionally, to facilitate thermal dissipation and air ventilation, these metal panels are further designed with ventilation holes. As long as the diameter of these holes is smaller than a fraction of the wavelength of the radiated signals, the panels can effectively shield against radiation leakage. The average diameter of these holds ranges from 2.0 to 5 mm. However, as network devices are developed to operate at higher frequencies (e.g., 25 GHz and above), the wavelength of the radiated waves becomes much smaller. When the fractional wavelength of these signals falls below the diameter of the ventilation holes, energy leakage through these holes becomes a concern.

Conventional methods to reduce radiated emissions each come with their own limitations. One approach is to use thicker metal sheets to reduce emissions, but this increases both the cost and weight of the network device, making it less practical. Another method is the non-uniform placement of holes to achieve destructive interference of the emissions. While this method can help with EMI, it does not use the front panel space efficiently and worsens airflow, compromising thermal management. A third method involves making the holes smaller to reduce emissions. Although effective for EMI reduction, this approach also restricts airflow, making it challenging to meet thermal requirements without adding additional heat dissipation features.

The present disclosure introduces a method that blends traditional manufacturing with added material processes to improve EMI shielding without adding significant material, weight, or cost. In one embodiment, a sparse mesh may be added to the vent panel of an electronic device (e.g., router). The sparse mesh may enclose the inner perimeter of each vent hole within the panel, forming a cell structure. The holes in the sparse mesh may be designed to be smaller than the fraction of a wavelength of the signals to effectively block EMI. Additionally, since the mesh allows air to pass through, the structure may maintain adequate ventilation, avoiding the need for additional cooling features that would otherwise add cost and complexity. Therefore, by using a thin sparse mesh on top of a front panel, the electronic device may effectively enhance its EMI performance to reduce radiated emissions while maintaining proper ventilation for thermal management.

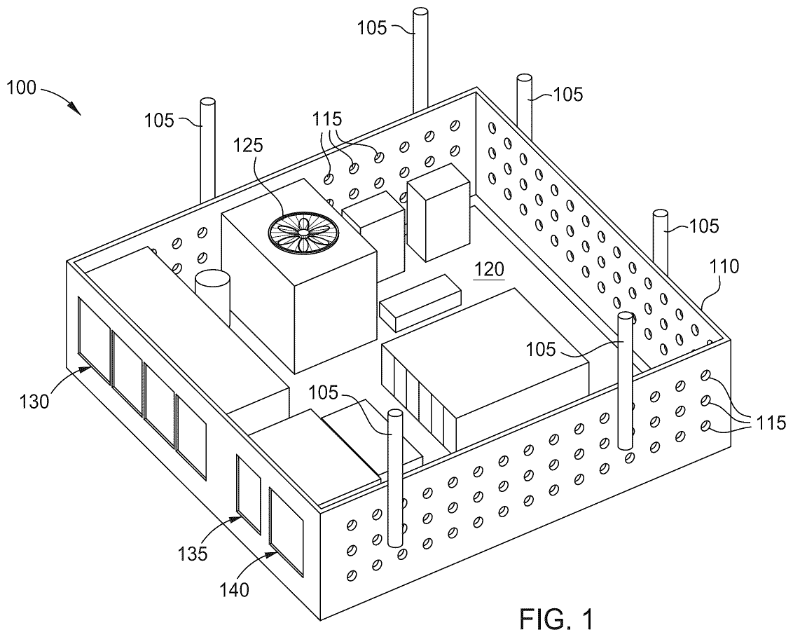

FIG. 1 shows an example router 100 with panels for EMI shielding, according to some embodiments of the present disclosure.

As illustrated, the router 100 includes a main circuit board 120, which contains the electronic circuits and components necessary for the router's operations. The router 100 further includes a cooling fan 125, which serves to maintain optimal (or at least improved) operating temperatures by facilitating airflow within the enclosure.

The cooling fan 125 and the main circuit board 120 are enclosed by panels 110. These panels 110 form an enclosure that protects these internal components from environmental factors (e.g., dust, moisture, physical damages). Additionally, the panels 110 provide EMI shielding, effectively preventing (or at least reducing) radiation generated by the internal components from escaping the enclosure. Typically, there are regulatory requirements that govern EMI control. These regulatory requirements are designed to prevent electronic devices from emitting excessive electromagnetic interference, which can affect the performance of other electronic devices. By using the panels 110, the router 100 ensures compliance with these regulatory requirements.

To provide adequate ventilation and facilitate heat dissipation, as depicted, the panels are designed with ventilation holes 115. These holes are placed to maximize (or at least improve) airflow across the internal components, to ensure that heat generated by the circuit board 120 and other components is effectively dissipated. In some embodiments, the size and distribution of the ventilation holes 115 may be calculated to maintain a balance between providing sufficient airflow and minimizing EMI leakage.

Six external antennas 105 are located outside the enclosure of the router 100 to maximize (or at least improve) signal strength and coverage. While six antennas are depicted for conceptual clarity, in some embodiments, any number of antennas 105 (including one) may be included within the router 100. The actual number may vary depending on the router's specifications and network requirements. In some embodiments, the router may include internal antennas within the enclosure for improved aesthetics and protection from external damage.

As illustrated, the router 100 further includes multiple ports for network connectivity and power supply on its back side. These include multiple local area network (LAN) ports 135 for connecting local devices, a wide area network (WAN) port 130 for internet connection, and a power cable port 140 to supply the required electrical power to the router.

The panels 110 may be made from any conductive materials effective at providing EMI shielding, such as aluminum, cold rolled steel, or stainless steel. The size of the ventilation holes typically ranges from 2.0 mm to 5 mm to ensure effective EMI shielding. However, as the router is developed to operate at higher frequencies (e.g., 25 GHz or above), the wavelength of the radiated signal become much smaller (e.g., 1.2 cm for 25 GHz). When the fractional wavelength of these signals (e.g., 3 mm for 25 GHz) falls below the diameter of the ventilation holes (e.g., 5 mm), it may result in increased EMI leakage.

To reduce EMI leakage without adding weight or cost, a sparse mesh may be added on top of the panels 110. In some embodiments, the sparse mesh may be composed of conductive, resistant, or ferromagnetic materials, provided these materials offer effective EMI shielding or dissipation. In some embodiments, the thickness and width of each strand in the mesh may be calculated to provide proper EMI enhancement, especially when the electronic device is operating at higher frequencies (e.g., 25 GHz or above). A thicker mesh may offer greater attenuation of EMI, providing better protection in environments where electromagnetic disturbances are more intense.

The sparse mesh may enclose or cover the inner perimeter of each ventilation hole 115. The mesh may include mesh holes (or gaps) that are smaller than the ventilation holes 115, providing effective EMI shielding when the router 100 operates at higher frequencies (e.g., 25 GHz or above). Also, these holes may allow air ventilation for heat dissipation, to ensure that the router 100 satisfies its thermal requirements without the need for additional cooling features. In some embodiments, the size of the mesh holes (or gaps) may be designed to achieve a balance between EMI shielding and ventilation, such as being smaller than the fractional wavelength of the signals (e.g., 3 mm for 25 GHz) to block EMI effectively but large enough to allow sufficient airflow for proper heat dissipation.

In embodiments where enhanced cooling is needed, large ventilation holes 115 may be incorporated into the mesh panels to facilitate increased air flow. However, large openings may also lead to higher EMI, increasing the risk of disruption. In this configuration, a mesh designed with smaller apertures may be added to optimize the design. The mesh may reduce EMI while preserving the benefits of increased air ventilation.

The figure depicts a router 100 as an example electronic device that uses panels for EMI shielding and, when operating at higher frequencies, adds a sparse mesh on top of the panels for enhanced shielding. The example router 100 is provided for conceptual clarity. In some embodiments, other types of devices used in wired and/or wireless communication may also utilize the disclosed methods for enhanced EMI shielding. Examples of such devices may include, but are not limited to, access points (APs), station devices (STAs), network switches, wireless LAN controllers (WLCs), and other network infrastructure equipment.

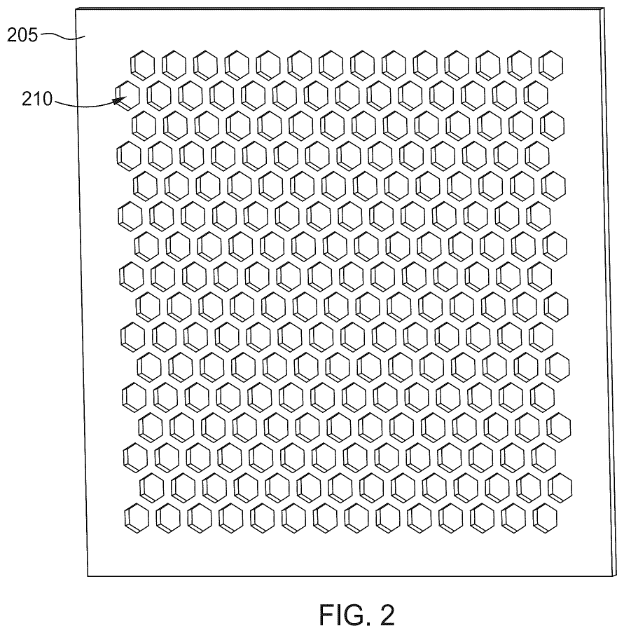

FIG. 2 shows an example panel 205 with ventilation holes 210, according to some embodiments of the present disclosure. The example panel 205 is a conventional panel used in electronic devices, and the ventilation holes 210 within the panel are designed for cooling purposes. The panel 205 may be made from any conductive materials such as aluminum, cold rolled steel, or stainless steel, which are effective at providing EMI shielding and structural protection for the internal components (e.g., circuit board 120 of FIG. 1).

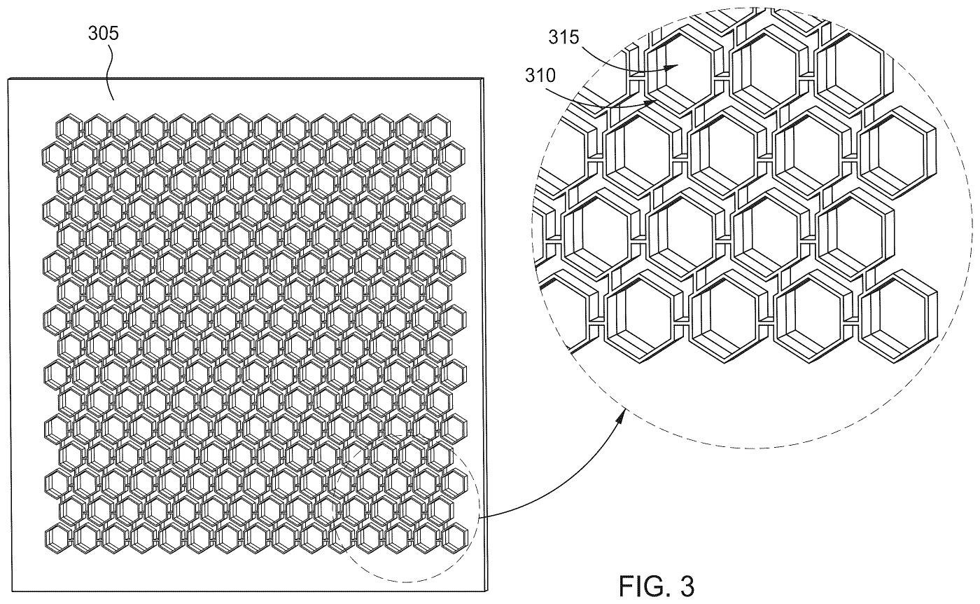

In some embodiments, the ventilation holes 210 may be placed across the panel to maximize (or at least improve) air flow, facilitating heat dissipation from the electronic components within the enclosure. In some embodiments, the thickness of the panel 205 may range from 1 mm or thicker, depending on EMI shielding needs or other configuration requirements. In some embodiments, the size of these ventilation holes 210 may vary based on the thermal requirements and EMI shielding needs. The diameter of these holes may ranges from 2.0 mm to 5 mm. As discussed above, when the electronic device (e.g., router 100 of FIG. 1) operates at higher frequencies, such as 25 GHz or above, the wavelength of the radiated interference becomes smaller. Specifically, the wavelength at 25 GHz is approximately 1.2 cm, and the 1/20 of a wavelength is 0.6 mm. When the fractional wavelength of these signals (e.g., 0.63 mm) is within a 1/20 or 1/10 of the diameter of the ventilation holes (e.g., 5 mm), it may result in increased radiated emissions. To address this issue, a sparse mesh may be added to the panel 205 to improve EMI shielding, as more detailed in FIG. 3.

As illustrated in FIG. 2, the ventilation holes 210 are hexagonal. The ventilation holes 210 are provided for conceptual clarity. In some embodiments, other shapes, such as circle or square, may be used. Within the example panel 205, the ventilation holes 210 are equally distributed across the panel 205 to ensure uniform cooling. In some embodiments, the holes 210 may be placed more densely near potential heat-generating components and more sparely in areas farther from these components.

FIG. 3 shows an example panel with added sparse mesh 305 for enhanced EMI shielding, according to some embodiments of the present disclosure.

As illustrated, a sparse mesh is attached to the panel to provide improved EMI shielding. The sparse mesh is designed to enclose or cover the inner perimeter 310 of each ventilation hole. This configuration enables that mesh cells 315 within the sparse mesh covers each opening within the panel.

The mesh may be attached to the panel using various methods. In some embodiments, a conductive adhesive may be used to bond the mesh to the panel. The conductive adhesive may provide both a strong attachment and electrical conductivity for effective EMI shielding. In some embodiments, the mesh may be soldered to the panel (e.g., at multiple points around each ventilation hole). This method may provide a secure enclosure for each hole and a conductive bond. In some embodiments, mechanical fasteners may be used to attach the mesh to the panel. Specifically, physical connectors may be added between the mesh and the panel to ensure the mesh encloses the inner perimeter 310 of each ventilation hole on the panel securely. In some embodiments, the overall device enclosure, consisting of a panel with ventilations holes and corresponding mesh cells covering the inner perimeters of each hole, may be produced using advanced 3-dimensional (3D) printing technology. In some embodiments, the mesh itself may be 3D printed and positioned on a prefabricated panel with the ventilation holes.

FIG. 4 shows a close-up view of a panel with added sparse mesh 305, according to some embodiments of the present disclosure. As illustrated, the mesh is aligned to enclose the inner perimeter 310 of each ventilation hole, providing mesh cells 315 that cover every opening within the panel. Within each mesh cell 315, the mesh includes smaller mesh holes (or gaps) that equal to or smaller (typo: or smaller) than the ventilation holes. These mesh holes (or gaps) may effectively prevent EMI leakage when the device operates at higher frequencies. Additionally, the mesh holes (or gaps) may facilitate air ventilation for heat dissipation, allowing the device to meet its thermal requirements without the need for additional cooling features. In some embodiments, the size of the mesh hole (or gap) may be determined to achieve a balance between EMI shielding and airflow. The mesh holes (or gaps) may be designed to be smaller than the fractional wavelength of the signals (e.g., 3/10 mm for 25 GHz) to provide effective EMI shielding, while also being large enough to ensure sufficient airflow for proper heat dissipation.

In some embodiments, with the addition of the sparse mesh, ventilation holes may be designed slightly larger to allow more air flow, while still maintaining effective EMI shielding.

In some embodiments, the thickness and width of the sparse mesh may also affect the performance of EMI shielding. The width of the sparse mesh may refer to the horizontal dimension of each strand in the mesh. The thickness of the sparse mesh may refer to the measurement of the strand's depth, perpendicular to the plane of the mesh. Table 1 below shows that the effectiveness of EMI shielding improves as the thickness of the sparse mesh increases. As shown, a sparse mesh of 1 mm thickness combined with a panel of 1 mm thickness may achieve similar EMI performance as a panel of 2 mm thickness without any mesh. A very thin sparse mesh with a width and thickness of only 0.1 mm helps reduce the penetrated energy through the holes by 0.88 dB.

TABLE 1

| | EMI Performance |
|---|---|
| Enclosure Configuration | (s21/dB) at 25 GHz |
| 1 mm wall without a sparse mesh | −22.88 |
| 2 mm wall without a sparse mesh | −34.32 |
| 1 mm wall with a sparse mesh of 0.1 mm | −23.76 |
| thickness and 0.1 mm width | |
| 1 mm wall with a sparse mesh of 0.2 mm | −24.98 |
| thickness and 0.1 mm width | |
| 1 mm wall with a sparse mesh of 0.5 mm | −28.12 |
| thickness and 0.1 mm width | |
| 1 mm wall with a sparse mesh of 1 mm | −34.57 |
| thickness and 0.1 mm width | |

Table 2 below provides the materials used and the weight impact of panels with and without sparse mesh. As depicted, the weight for a 1 mm panel without a sparse mesh is 0.26 kg. The weight for a 2 mm panel without a sparse mesh is 0.53 kg. The weight for a 1 mm panel with a 1 mm thickness mesh is 0.28 kg. The material saving can be calculated using the equation below:

$$\% material saving = \frac{\begin{matrix}( weight of 2 mm wall design - \\ weight of 1 mm wall and 1 mm mesh design )\end{matrix}}{weight of 2 mm wall design}$$

As discussed, 1 mm panel with a 1 mm thickness mesh may achieve similar EMI shielding performance as a 2 mm panel without a sparse mesh. According to the Table 2, the 1 mm panel with a sparse mesh may save up to 47.38% in materials compared with a 2 mm panel. The weight of the design for the 1 mm panel is close to the weight of the design for the 1 mm panel with a 1 mm thickness mesh. Therefore, using sparse mesh may effectively improve EMI performance without adding significant weight or material costs. This approach offers a more efficient and resource-saving solution.

TABLE 2

| Enclosure | EMI Performance | Weight of | % material |
|---|---|---|---|
| Configuration | (s21/dB) at 25 GHz | Design (kg) | saving |
| 1 mm wall without | −22.88 | 0.26 | — |
| a sparse mesh | | | |
| 2 mm wall without | −34.3 | 0.53 | — |
| a sparse mesh | | | |
| 1 mm wall with a | −34.3 | 0.28 | 47.38 |
| sparse mesh of | | | |
| 1 mm thickness | | | |
| and 0.1 mm width | | | |

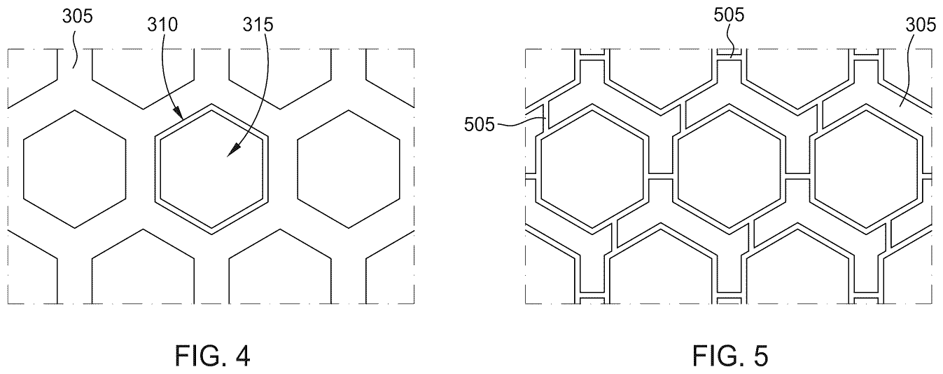

FIG. 5 shows a close-up view of a panel with added structural supports 505 between mesh cells, according to some embodiments of the present disclosure. As illustrated, structural supports 505 are added between the mesh cells, providing additional stability and durability to the sparse mesh setup. In some embodiments, the structural supports 505 may be made of conductive materials, such as aluminum, copper, or stainless steel, to further improve the EMI shielding performance of the mesh. These supports may be attached through various methods, such as adhesive bonding, soldering, or using mechanical fasteners.

In some embodiments, individual sparse mesh pieces may be attached separately to cover each ventilation holes, with structural supports 505 subsequently attached to connect these individual meshes into a cohesive grid. This method may allow precise coverage and customized shielding for every opening. In some embodiments, a single sheet of mesh may be attached to the panel as a whole. The mesh encloses the inner perimeter of each ventilation hole to form mesh cells. In such configurations, additional structural supports 505 may be added to further secure the mesh and improve its stability.

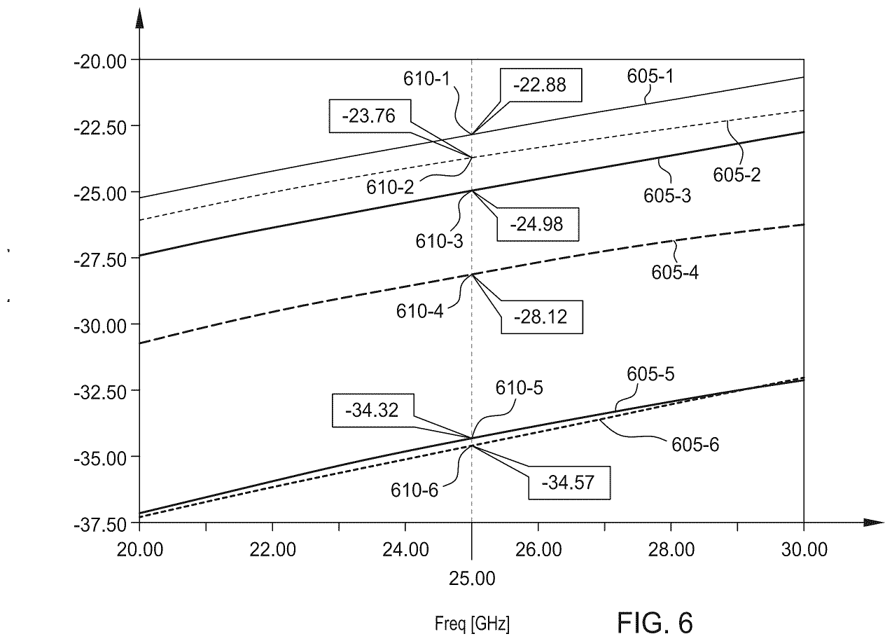

FIG. 6 shows EMI performance of a device across signal frequencies with different panel configurations, according to some embodiments of the present disclosure. The device may correspond to the router 100 as depicted in FIG. 1 or any other types of electronic devices used in wired and/or wireless communication.

As illustrated, the horizontal axis (x axis) represents the device's operating frequency in gigahertz (GHz). Higher frequencies often provides greater bandwidth, which allows more data to be transmitted and/or processed over time. The vertical axis (y axis) represents the EMI performance in decibels (dB). The negative values indicate the degree to which the EMI is being reduced by the shielding. For example −27.5 dB represents that the shielding is reducing the EMI by 27.5 decibels. The more negative the value, the more effective the shielding is at reducing EMI. Line 605-1 represents a 1 mm panel without a sparse mesh. Line 605-2 represents a 1 mm panel with a sparse mesh of 0.1 mm thickness and 0.1 mm width. Line 605-3 represents a 1 mm panel with a sparse mesh of 0.2 mm thickness and 0.1 mm width. Line 605-4 represents a 1 mm panel with a sparse mesh of 0.5 mm thickness and 0.1 mm width. Line 605-5 represents a 2 mm panel without a sparse mesh. Line 605-6 represents a 1 mm panel with a sparse mesh of 1 mm thickness and 0.1 mm width. As shown in the figure, as the frequency increases, EMI performance degrades, indicated by a decrease in the degree of EMI reduction. For example, for a 1 mm panel without a sparse mesh, the EMI reduction provide by the panel drops from 25.5 dB to 20.7 dB as the operating frequency increases from 20 GHz to 30 GHz. The degradation in EMI performance may be caused by the reduction in the wavelength of the signals at higher frequencies. Since the size of the ventilation holes in the panel remain unchanged (e.g., 5 mm), the smaller wavelengths relative to these holes allow more electromagnetic interference to escape, which therefore increases EMI leakage.

As illustrated, when operating at 25 GHz, the EMI performance for a 1 mm panel without a sparse mesh is measured at −22.88 dB (601-1), which indicates that the panel is reducing the EMI by 22.88 dB. With the attachment of a sparse mesh of 0.1 mm thickness and 0.1 mm width, the EMI performance is measured at −23.76 dB (601-2), representing the panel is reducing the EMI by 23.76 dB. By comparing these values, it can be determined that adding a thin sparse mesh with a width and thickness of only 0.1 mm improve the EMI reduction by 0.88 dB. The EMI performance for a 2 mm panel without a sparse mesh is measured at −34.32 dB (610-5), which is close to the EMI performance of −34.57 dB (610-6) for a 1 mm panel enhanced with a sparse mesh of 1 mm thickness and 0.1 width. Therefore, by adding a sparse mesh, the device's EMI shielding performance may be effectively enhanced without significantly increasing its cost and weight.

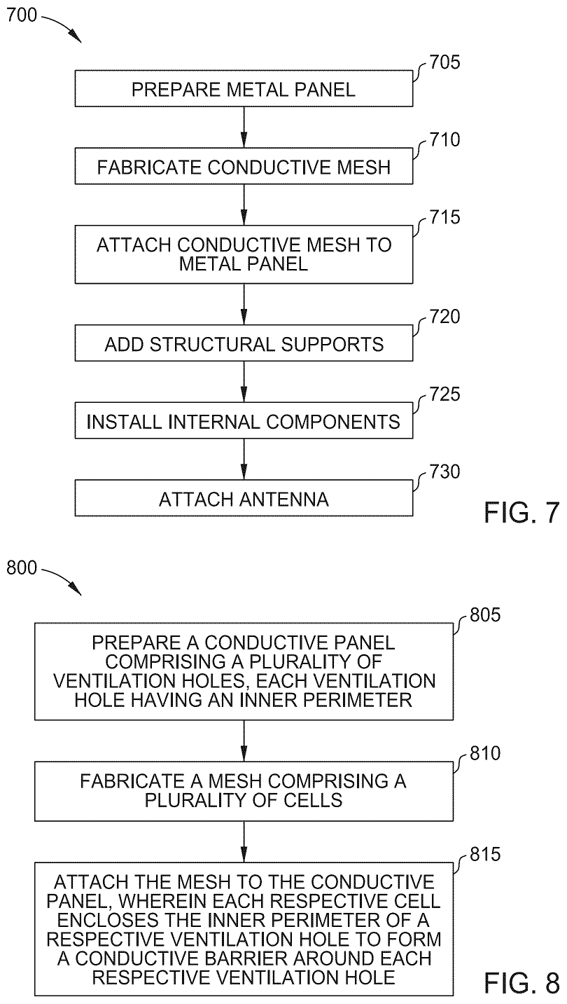

FIG. 7 shows an example method 700 for manufacturing a panel with sparse mesh for enhanced EMI shielding, according to some embodiments of the present disclosure. In some embodiments, the example method 700 may be performed by a panel manufacturer, which is specialized in producing panels used for EMI shielding in electronic devices. In some embodiments, the example method 700 may be performed by device manufacturers, which have specific requirements for the mesh configuration and its integration into the product design.

The method 700 begins at block 705 with the preparation of the panel. Conductive materials with effective EMI shielding properties (e.g., aluminum, copper, stainless steel) may be used for the panels. In some embodiments, the thickness of the panel may range from 1 to 1.4 mm, depending on the required strength and shielding effectiveness. Ventilation holes may be designed within the panel. The size and pattern of the ventilation holes may be determined to provide proper EMI shielding and adequate heat dissipation.

At block 710, the mesh is fabricated using a variety of materials, including conductive materials, resistant materials, and ferromagnetic materials, provided these materials offer effective EMI shielding properties. In some embodiments, the thickness and width of each strand in the mesh may be calculated to provide proper EMI enhancement, especially when the electronic device is operating at higher frequencies (e.g., 25 GHz or above). In some embodiments, the size of the holes in the mesh may be designed to be smaller than those in the panel, typically less than a quarter of the wavelength of the device's operating frequencies, to optimize EMI shielding while still allowing for effective heat dissipation.

At block 715, the mesh is attached to the panel. Various methods may be used for the attachment, such as adhesive bonding, soldering, or using mechanical fasteners. In some embodiments, the mesh may be aligned to enclose the inner perimeter of each ventilation hole within the panel. Such alignment enables mesh cells within the mesh to cover each opening within the panel, effectively forming a conductive barrier around each hole for enhanced EMI shielding.

At block 720, structural supports, such as conductive frames, are added between the mesh cells to increase the structural stability of the mesh and enhance its effectiveness in EMI shielding. These supports may be made from the same materials as the mesh. In some embodiments, the structural supports and conductive mesh may be added together to the metal panel. This allows for a uniform integration and enhances the overall strength and EMI shieling from the start of the assembly process. In some embodiments, the conductive mesh may be attached first, followed by the addition of the structure supports. The subsequent addition of the structural supports provides the flexibility to adjust the support system based on the specific needs of the enclosure, such as targeted reinforcement in areas experiencing higher mechanical stress.

At block 725, the prepared panel is used as an enclosure for an electronic device (e.g., router 100 of FIG. 1). Internal components like the circuit boards (e.g., 120 of FIG. 1) and cooling fans (e.g., 125 of FIG. 1) are installed within the enclosure.

At block 730, external components such as antennas are installed outside the enclosure. In some embodiments, the antennas may be mounted in predetermined positions to optimize the device's wireless communication capabilities.

FIG. 8 is a flow diagram depicting an example method 800 for forming an enclosure with reduced radiated emission, according to some embodiments of the present disclosure.

At block 805, a conductive panel comprising a plurality of ventilation holes is prepared, each ventilation hole having an inner perimeter.

At block 810, a mesh comprising a plurality of cells is prepared.

At block 815, the mesh is attached to the conductive panel, where each respective cell encloses the inner perimeter of a respective ventilation hole to form a conductive barrier around each respective ventilation hole.

In some embodiments, one or more structural supports may be added to the conductive panel, where the one or more structural supports comprises frames that connect adjacent cells, of the plurality of cells, within the mesh.

In some embodiments, each respective cell may comprise a plurality of mesh holes. In some embodiments, a size of each mesh hole may be smaller than a quarter wavelength of an operating frequency of the electronic device. In some embodiments, a size of each mesh hole may be larger than a threshold that allows sufficient airflow through the mesh to satisfy thermal requirements of the electronic device.

In some embodiments, the mesh may be attached to the conductive panel using at least one of conductive adhesives, soldering, or mechanical fasteners.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a computer program product embodied in one or more computer readable medium(s) having computer readable program code embodied thereon.

Program code embodied on a computer readable medium may be transmitted using any appropriate medium, including but not limited to wireless, wireline, optical fiber cable, RF, etc., or any suitable combination of the foregoing.

Computer program code for carrying out operations for embodiments of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to flowchart illustrations and/or block diagrams of methods, apparatuses (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

These computer program instructions may also be stored in a computer readable medium that can direct a computer, other programmable data processing apparatus, or other device to function in a particular manner, such that the instructions stored in the computer readable medium produce an article of manufacture including instructions which implement the function/act specified in the block(s) of the flowchart illustrations and/or block diagrams.

The computer program instructions may also be loaded onto a computer, other programmable data processing apparatus, or other device to cause a series of operational steps to be performed on the computer, other programmable apparatus or other device to produce a computer implemented process such that the instructions which execute on the computer, other programmable data processing apparatus, or other device provide processes for implementing the functions/acts specified in the block(s) of the flowchart illustrations and/or block diagrams.

The flowchart illustrations and block diagrams in the Figures illustrate the architecture, functionality, and operation of possible implementations of systems, methods, and computer program products according to various embodiments. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

In view of the foregoing, the scope of the present disclosure is determined by the claims that follow.

We claim:

1. An enclosure for an electronic device, comprising:
a conductive panel comprising a plurality of ventilation holes, each ventilation hole having an inner perimeter; and
a mesh attached to the conductive panel, the mesh comprising a plurality of cells,
wherein each respective cell encloses the inner perimeter of a respective ventilation hole to form a conductive barrier around each respective ventilation hole.

2. The enclosure of claim 1, wherein the mesh is comprised of at least one material selected from a ground comprising conductive materials, resistant materials, and ferromagnetic materials.

3. The enclosure of claim 1, wherein the mesh is attached to the conductive panel using at least one of conductive adhesives, soldering, or mechanical fasteners.

4. The enclosure of claim 1, further comprising one or more structural supports, wherein the one or more structural supports comprises frames that connect adjacent cells, of the plurality of cells, within the mesh.

5. The enclosure of claim 4, wherein the structural supports are attached to the conductive panel using conductive adhesives.

6. The enclosure of claim 1, wherein each respective cell comprises a plurality of mesh holes.

7. The enclosure of claim 6, wherein a size of each mesh hole is smaller than a quarter wavelength of an operating frequency of the electronic device.

8. The enclosure of claim 6, wherein a size of each mesh hole is larger than a threshold that allows sufficient airflow through the mesh to satisfy thermal requirements of the electronic device.

9. A method for forming an enclosure for an electronic device to shield electromagnetic interference, comprising:
preparing a conductive panel comprising a plurality of ventilation holes, each ventilation hole having an inner perimeter;
fabricating a mesh comprising a plurality of cells; and
attaching the mesh to the conductive panel, wherein each respective cell encloses the inner perimeter of a respective ventilation hole to form a conductive barrier around each respective ventilation hole.

10. The method of claim 9, further comprising adding one or more structural supports to the conductive panel, wherein the one or more structural supports comprises frames that connect adjacent cells, of the plurality of cells, within the mesh.

11. The method of claim 9, wherein the mesh is comprised of at least one material selected from a ground comprising conductive materials, resistant materials, and ferromagnetic materials.

12. The method of claim 9, wherein each respective cell comprises a plurality of mesh holes.

13. The method of claim 12, wherein a size of each mesh hole is smaller than a quarter wavelength of an operating frequency of the electronic device.

14. The method of claim 12, wherein a size of each mesh hole is larger than a threshold that allows sufficient airflow through the mesh to satisfy thermal requirements of the electronic device.

15. The method of claim 9, wherein the mesh is attached to the conductive panel using at least one of conductive adhesives, soldering, or mechanical fasteners.

16. An apparatus for shielding electromagnetic interference in an electronic device, comprising:
a conductive panel comprising a plurality of ventilation holes, each ventilation hole having an inner perimeter; and
a mesh attached to the conductive panel, the mesh comprising a plurality of cells,
wherein each respective cell encloses the inner perimeter of a respective ventilation hole to form a conductive barrier around each respective ventilation hole.

17. The apparatus of claim 16, wherein each respective cell comprises a plurality of mesh holes.

18. The apparatus of claim 17, wherein a size of each mesh hole is smaller than a quarter wavelength of an operating frequency of the electronic device.

19. The apparatus of claim 17, wherein a size of each mesh hole is larger than a threshold that allows sufficient airflow through the mesh to satisfy thermal requirements of the electronic device.

20. The apparatus of claim 16, further comprising one or more structural supports, wherein the one or more structural supports comprises frames that connect adjacent cells, of the plurality of cells, within the mesh.
